(19) United States
(12) Patent Application Publication
(10) Pub. No.: US 2015/0130464 A1
(43) Pub. Date: May 14, 2015

(54) POWER CONVERTER FOR POWERING AN MRI GRADIENT COIL AND METHOD OF OPERATING A POWER CONVERTER

(71) Applicant: KONINKLIJKE PHILIPS N.V., EINDHOVEN (NL)

(72) Inventors: Hendrik Huisman, Eindhoven (NL); Marcus Leonardus Anna Caris, Eindhoven (NL)

(21) Appl. No.: 14/384,412

(22) PCT Filed: Mar. 5, 2013
(86) PCT No.: PCT/IB2013/051736

§ 371 Date: Sep. 11, 2014

Related U.S. Application Data
(60) Provisional application No. 61/609,588, filed on Mar. 12, 2012.

(51) Int. Cl. H02M 7/5387; G01R 33/385; G01R 33/54; H02M 1/12

(52) U.S. Cl. CPC H02M 7/5387; H02M 1/12; G01R 33/385; G01R 33/543
USPC 324/322; 363/41

(57) ABSTRACT

A power converter for powering a gradient coil (22) of a magnetic resonance examination system, comprising: a plurality of essentially identical switching cells (14, 16, 18), each switching cell (14, 16, 18) having a plurality of switching members (52) that are provided to switch between a conducting state configuration and an essentially non-conducting state configuration, and the switching cells (14, 16, 18) being provided to switch at at least a fundamental switching frequency fSW and in a pre-determined temporal relationship to each other, a pulse control unit (20) provided to control the pre-determined temporal relationship of switching of the switching cells (14, 16, 18) by providing switching pulses to the switching members (52) of the switching cells (14, 16, 18), wherein the pulse control unit (20) is provided to determine a correction for the pre-determined temporal relationship of the switching of the switching cells (14, 16, 18) from at least one electrical quantity each of each one of the plurality of switching cells (14, 16, 18), and to adjust the pre-determined temporal relationship according to the determined correction, such that at least one electrical quantity of a power converter output essentially has a zero amplitude at the fundamental switching frequency fSW; and a method of operating a power converter, particularly for powering a gradient coil (22) of a magnetic resonance examination system, for compensating inductance asymmetries.

### FIELD OF THE INVENTION

The invention pertains to a power converter for powering a gradient coil of a magnetic resonance (MR) examination system and a method of operating a power converter for compensating inductance asymmetries.

### BACKGROUND OF THE INVENTION

In the field of power converters it is known to employ semiconductor switches configured in switching cells that allow for different directions of current flow. The semiconductor switches are controlled by switching pulses of a fundamental switching frequency that are pulse width-modulated with a variable duty cycle.

In many types of power converters it is desirable to attain an effective pulse width-modulation (PWM) frequency as high as possible. Such high frequencies are in general advantageous for attaining high reaction speed (high bandwidth) and accurate signal construction. Moreover, such high frequencies can lead to smaller inductive and capacitive storage elements, thereby reducing system size, weight, and cost.

Practical semiconductor power switches feature a certain energy loss for every switching event. This energy loss depends on the technology and materials used (metal-oxide-semiconductor (MOS), bipolar junction; silicon (Si), silicon carbide (SiC), gallium nitride (GaN)), a voltage rating of the device, and the circuit conditions; i.e. voltage and current applied directly before and after the switching event. Due to this energy loss, a semiconductor power switch can be used sensibly only up to a certain switching frequency. For gate turn-off thyristors (GTO), this frequency is typically several hundred Hertz (Hz), for medium-voltage insulated gate bipolar transistors (IGBT) several kHz, and for medium-voltage MOS-field effect transistors (MOSFET) several tens to hundreds of kHz. These are not meant to be absolute numbers. However, frequencies in excess of the indicated levels lead to increased dissipation in the device, thereby to low circuit efficiency, and in the limit to an unworkable circuit.

Interleaving and multilevel circuits offer a way out of this design problem. In such circuits, a plurality of essentially identical switching cells is operated in parallel and/or series. The individual switching cells are operated with a time offset of T_{SW}/N with respect to each other, where T_{SW} is the switching cycle time of an individual switching cell, and N is the number of cells. Thereby, the apparent switching frequency is increased by a factor N. Each individual switching cell operates with a moderate switching frequency and processes 1/N of the total power, which allows a modular design.

The term “interleaving” is commonly used for switching cells operating in parallel, i.e. the output current of the system is N times the current of an individual switching cell, whereas the voltage is the same for system and switching cell. “Multilevel” is used for systems which use summing of the cell voltages, i.e. the output voltage of the system is N times larger than the output voltage of an individual cell, but the switching cell currents are equal. Examples of both circuit topologies are shown in FIG. 1.

A correct operation of an interleaving power converter greatly relies on symmetry of the switching cells. As such, an inductance per cell is of key importance to attain a theoretically possible functionality. This inductance depends on electrical properties of discrete inductors, which typically show tolerances of 5 to 10% around their nominal values. Additionally, due to the circuit geometry, additional inductances such as connecting wires and bus bars are introduced in the circuit which can in most cases not be made completely equal among cells in an economically reasonable effort.

Exploiting the full potential of an interleaving concept is therefore not possible for high values of N at reasonable cost. Therefore, methods to overcome asymmetries caused by circuit tolerances are needed. In the prior art [1] it has been suggested to select an order in which the switching cells are triggered based on amplitudes of ripple currents. This method leads to some suppression, but in general not to complete annihilation, of the fundamental switching frequency.

### SUMMARY OF THE INVENTION

It is therefore an object of the invention to provide a power converter with an improved compensation of a fundamental switching frequency component of the power converter output stemming from tolerances inherent to the power converter.

In one aspect of the present invention, the object is achieved by a power converter for powering a gradient coil of a magnetic resonance (MR) examination system, comprising:

a plurality of essentially identical switching cells, each switching cell having a plurality of switching members that are provided to switch between a conducting state configuration and an essentially non-conducting state configuration, and the switching cells being provided to switch at at least a fundamental switching frequency and in a pre-determined temporal relationship to each other,

a pulse control unit provided to control the pre-determined temporal relationship of switching of the switching cells by providing switching pulses to the switching members of the switching cells,

wherein the pulse control unit is provided to determine a correction for the pre-determined temporal relationship of the switching of the switching cells from at least one electrical quantity each of each one of the plurality of switching cells, and to adjust the pre-determined temporal relationship according to the determined correction, such that at least one electrical quantity of a power converter output essentially has a zero amplitude at the fundamental switching frequency.

The phrase “electrical quantity”, as used in this application, shall be understood particularly to encompass electrical current, electrical voltage, and electrical resistance. It may as well encompass a component of the electrical current or a component of the electrical voltage or a resistance, at a specific frequency or at various frequencies, wherein a “frequency” may encompass a discrete frequency as well as a center frequency within a frequency band. The phrase “essentially zero amplitude”, as used in this application, shall be understood particularly as an amplitude that is smaller in comparison to a largest amplitude of the quantity at a different frequency by a factor of at least 20, preferably of at least 50.

To illustrate the advantage of the invention, an application of the power converter for powering a gradient coil of a magnetic resonance (MR) examination system is taken as an example. In such a system, especially an integral of a gradient current ripple is of prime importance for an image quality. An integral criterion is very sensitive to low frequencies such as the above-mentioned fundamental switching frequency. In a state-of-the-art power converter for an MR gradient coil, an output voltage of a switching power converter passes through a non-dissipative LC-filter before it is applied to the gradient coil, as is shown in FIG. 1. The combination of the LC-filter and the gradient coil acts as a third-order filter. For the ripple in a sum of the switching cell currents, an effective order of the filtering action is one less than that, i.e. the net filter is of order two. The integral criterion can be interpreted as an additional filtering action. The combined operation therefore acts as a third-order filter, effectively suppressing higher harmonics, but being much less effective for the lower ones.

As an example, a case is considered where a cut-off frequency of an output filter of 5 kHz lies well below the fundamental switching frequency of the power semiconductors of 10 kHz. Here, all spectral components, including the fundamental switching frequency, will be processed by a part of the filter characteristic having a slope of −3 in a Bode plot, as is shown in FIG. 5.

With an attenuation of the fundamental frequency labeled as A (A is equal to 0.24254 in the example), the attenuation of the second harmonic then will be A/2³=A/8. For the third harmonic, the attenuation will be A/3³=A/27. In other words, a fundamental frequency with an amplitude which is only a twenty-seventh of the amplitude of the third harmonic, will have a comparable impact regarding the image quality. For different filter settings, numerical consequences may differ somewhat, but in most practical cases an elimination of even small fractions of the fundamental frequency will have a significant beneficial effect on the image quality.

In another aspect of the present invention, the essentially identical switching cells are connected in parallel and establish common output ports for connecting a load. Power supplies with interleaving switching cells may advantageously be used as current sources for powering loads.

In yet another aspect of the present invention, the essentially identical switching cells are connected in series and establish common output ports for connecting a load. Power supplies with switching cells connected in series may advantageously be used as voltage sources for powering loads.

In a preferred embodiment, a number of essentially identical switching cells is three. The correction for the pre-determined temporal relationship of the switching of the switching cells may in this case be expressed in a mathematically closed solution, so that it can be readily obtained in a calculation by the pulse control unit.

In another aspect of the invention, the essentially identical switching cells are designed as H bridges, each comprising semiconductor switches as switching members and at least one inductor. Thus, the power converter may power a load, in particular an inductive load like a gradient coil, such that a current provided at the power converter output may flow in any desired direction.

It is another object of the invention to provide a gradient coil unit of a magnetic resonance (MR) examination system, comprising at least one embodiment of a power converter as described herein, and at least one gradient coil. By that, a gradient coil may be realized that avoids encoding errors and hence image artifacts due to low signal-to-noise ratio, thus providing a reliable and faultless spatial encoding of a magnetic resonance signal of the MR examination system.

In another aspect, the invention is related to a method of operating a power converter, particularly for powering a gradient coil of a magnetic resonance (MR) examination system, that comprises a plurality of essentially identical switching cells, each switching cell having a plurality of switching members that are provided to switch between a conducting state configuration and an essentially non-conducting isolating state configuration, and the switching cells being provided to switch at at least a fundamental switching frequency and in a pre-determined temporal relationship to each other, and a pulse control unit provided to control the pre-determined temporal relationship of switching of the switching cells by providing switching pulses to the switching members of the switching cells, the method comprising the following steps:

determine at least one electrical quantity each of each one of the plurality of switching cells,

determine a correction for the pre-determined temporal relationship of the switching of the switching cells from the electrical quantities of each one of the plurality of switching cells, wherein the electrical quantities are individually assignable to the switching cells,

adjust the temporal relationship of the switching pulses provided to the switching members of the switching cells according to the determined correction such that at least one electrical quantity of a power converter output essentially has a zero amplitude at the fundamental switching frequency.

In yet another aspect, the invention is related to a software module provided to control a pre-determined temporal relationship of switching of switching cells of a power converter, particularly provided for powering a gradient coil of a magnetic resonance examination system. The power converter comprises a pulse control unit that is provided to control the pre-determined temporal relationship of switching of the switching cells between a conducting state configuration and an essentially non-conducting state configuration by providing switching pulses to the switching members of the switching cells, and the switching cells are provided to switch at at least a fundamental switching frequency fSW, so as to carry out the method described above, wherein the steps of the method are converted into a program code that is implementable in and executable by a pulse control unit of the power converter.

[1] O. Garcia, A. de Castro, P. Zumelis, J. A. Cobios. Digital-Control-Based Solution to the effect of non-idealities of the inductors in multiphase converters. IEEE Trans. on Power Electronics, vol. 22, no. 6, Nov. 2007, pp. 2155-2163.

### BRIEF DESCRIPTION OF THE DRAWINGS

These and other aspects of the invention will be apparent from and elucidated with reference to the embodiments described hereinafter. Such embodiment does not necessarily represent the full scope of the invention, however, and reference is made therefore to the claims and herein for interpreting the scope of the invention.

In the drawings:

FIGS. 1a and 1b show embodiments of gradient coil units in accordance with the invention in interleaved (FIG. 1a) and multilevel (FIG. 1b) converter configurations,

FIG. 2 illustrates output quantities of the interleaved power converter of FIG. 1 for an ideally symmetric configuration,

FIG. 3 illustrates the output quantities as in FIG. 2 for a non-symmetric configuration without applying a correction,

FIG. 4 illustrates frequency spectra of the interleaved power converter output quantities of FIGS. 2 and 3,

FIG. 5 depicts a frequency response of an electrical filter typically used in a gradient coil unit of an MRI examination system,

FIG. 6 illustrates the output quantities as in FIG. 3 for a non-symmetric configuration after applying a correction in accordance with the invention,

FIG. 7 illustrates a frequency spectrum of the interleaved power converter output quantities of FIG. 6,

FIG. 8 illustrates the correction in accordance with the invention in a vector diagram for a threefold interleaved converter configuration,

FIG. 9 illustrates another correction in accordance with the invention in a vector diagram for a fourfold interleaved converter configuration,

FIG. 10 illustrates frequency spectra of the fourfold interleaved power converter output quantities of FIG. 9, and

FIG. 11 depicts total currents of a power converter before and after applying the method in accordance with the invention in the time domain.

### DETAILED DESCRIPTION OF EMBODIMENTS

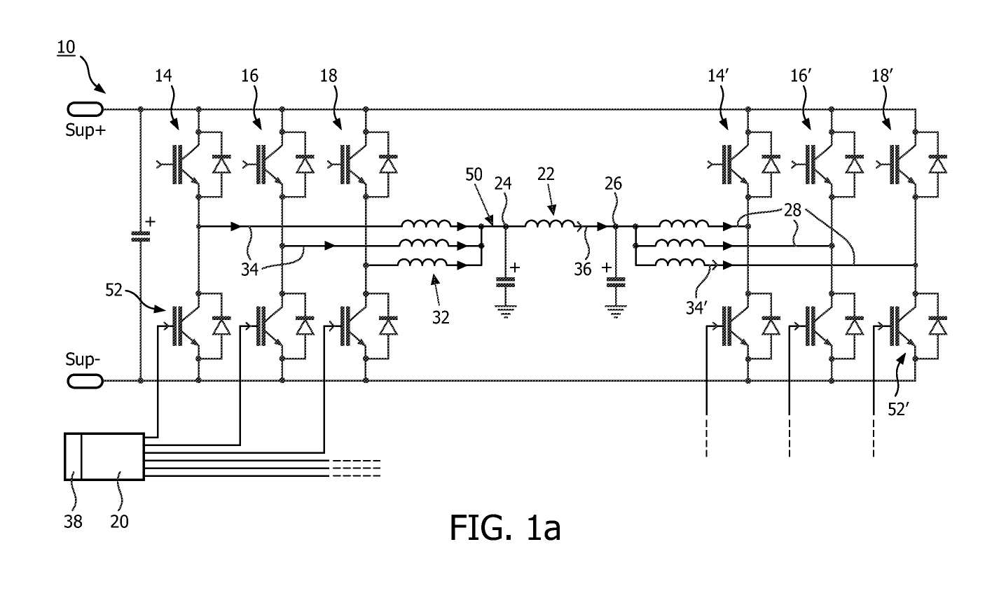

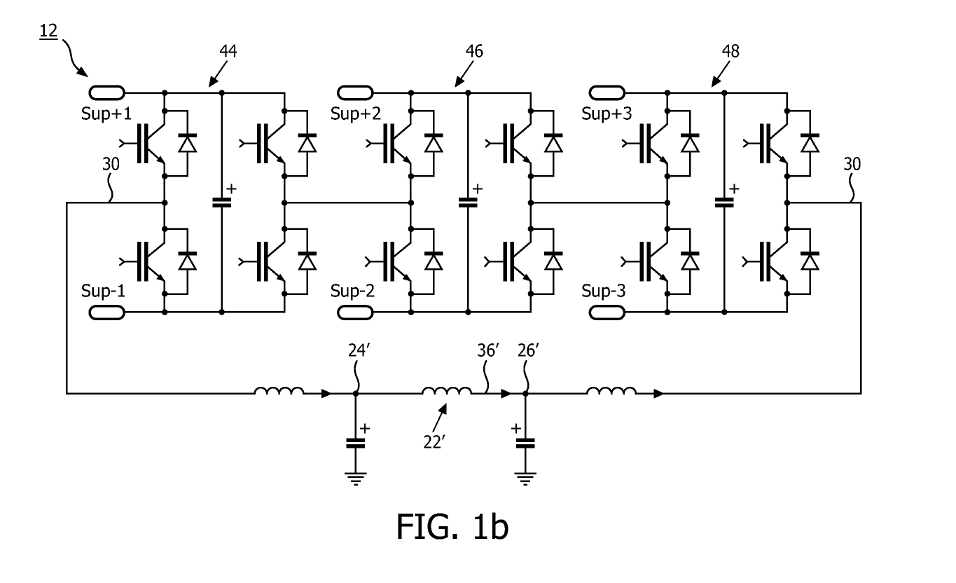

FIGS. 1a and 1b show embodiments of gradient coil units in accordance with the invention. The gradient coil units comprise a power converter of an interleaved configuration 10 (FIG. 1a) and another power converter of multilevel configuration 12 (FIG. 1b), respectively. In the sequel, the interleaved configuration 10 will be used in the description of the embodiments, but the invention can also be applied to power converters of multilevel configuration 12.

The power converters comprise three essentially identical switching cells 14, 16, 18 that are designed as an H bridge with four switching members 52 formed by semiconductor switches, antiparallel diodes, an inductor 32 and a filter, as commonly known by the one of skills in the art. The switching members 52 are provided to switch between a conducting state configuration and an essentially non-conducting state configuration, and the switching cells 14, 16, 18 are provided to switch at at least a fundamental switching frequency f_{SW} and in a pre-determined temporal relationship to each other. The power converter comprises a pulse control unit 20 that is provided to control the pre-determined temporal relationship of switching of the switching cells 14, 16, 18 by providing switching pulses to the switching members 52 of the switching cells 14, 16, 18. For the sake of clarity, lines required to transport the switching pulses from the pulse control unit 20 to the semiconductor switches are only hinted at in FIG. 1.

The semiconductor switches are shown in FIG. 1 as IGBTs, but could in general be designed as MOSFETs, or any other semiconductor switch that appears suitable to the one of skills in the art.

The power converters are provided for powering a gradient coil 22 of the gradient coil unit which is part of a magnetic resonance (MR) examination system that is not shown in further detail. The gradient coil 22 is connected with each of its two ends to power converter output ports 24, 26 constituted by two nodes that connect three output lines 28 of the H bridges carrying an individual output line current 34 each, so that a total current 36 flowing through the gradient coil 22 is a low pass-filtered superposition of the H bridge output line currents 34.

In prior art power converters, the pre-determined temporal relationship of the switching of the switching cells 14, 16, 18 is designed such that a phase shift exists between electric quantities of each of the switching cells 14, 16, 18 which are given by the output line currents 34 in the H bridge output lines 28, the phase shift being an integer fraction of 360 degrees. For the threefold interleaved converter configuration as shown in FIG. 1, the phase shift would be 360/3 degrees=120 degrees.

In the interleaved configuration 10 of the power converter, the three essentially identical switching cells 14, 16, 18 are connected in parallel and establish the output terminals as the common output ports 24, 26 for connecting the gradient coil 22.

In the multilevel configuration 12 of the power converter, the three essentially identical switching cells 44, 46, 48 are connected in series and establish output terminals as common output ports 24•, 26• for connecting a load by use of output lines 30 of the H bridges at ends of the series configuration.

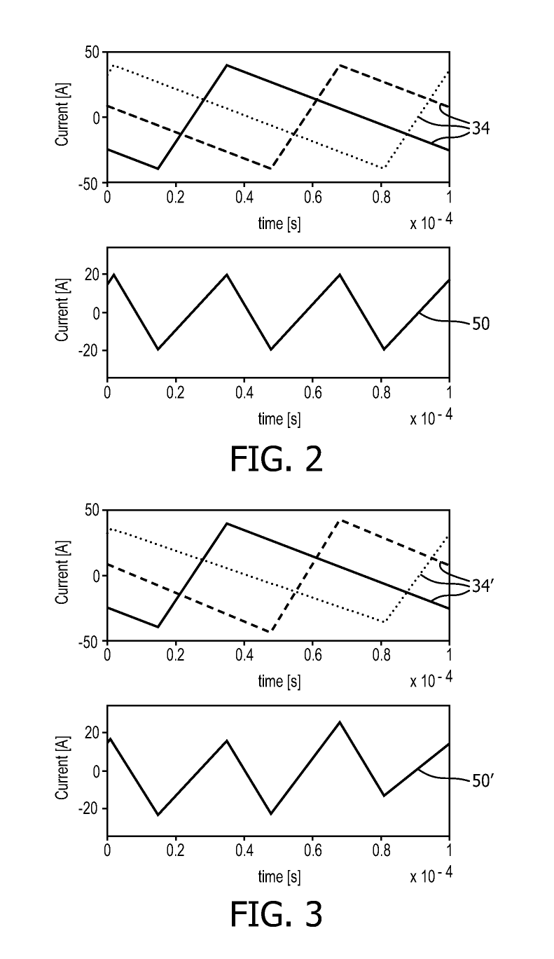

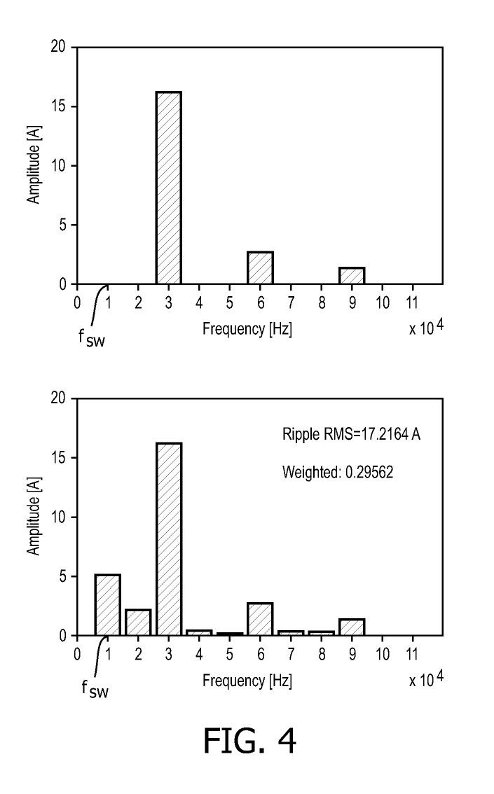

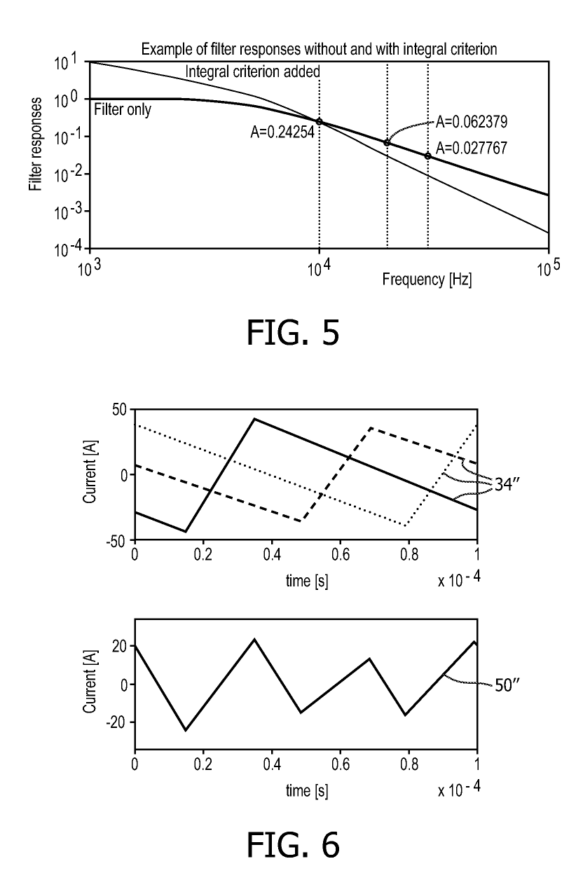

FIG. 2 illustrates the output quantities of each of the switching cells 14, 16, 18 which are given by the H bridge output line currents 34 of the interleaved power converter of FIG. 1, assuming an ideally symmetric configuration; i.e. the three switching cells 14, 16, 18 having identical electrical properties and, in particular, the inductors 32 having identical inductance values. The upper part of FIG. 2 shows the individual output line currents 34 with identical amplitudes, the lower part of FIG. 2 shows a sum current 50 as a superposition of the three output line currents 34. The switching cells 14, 16, 18 are being switched at a fundamental switching frequency f_{SW} of 10 kHz, equivalent to a cycle duration of 0.1 ms, with a duty cycle of 20% and a phase shift of 120 degrees. The sum current 50 therefore shows a lowest frequency component of 30 kHz (FIG. 4).

FIG. 3 shows a configuration of the power converter with identical switching cells 14, 16, 18 except for a variation of ±10% among inductance values of the inductors 32. The inequality of the switching cell inductors 32 leads to a different current ripple amplitude per switching cell 14, 16, 18, and thereby to an incomplete cancellation of the fundamental switching frequency f_{SW} (first harmonic) of the sum current 50•. A difference between the switching cell output line currents 34• is clearly visible in FIG. 3.

More instructive regarding a difference between the symmetric and the asymmetric configuration, than a presentation in the time domain are frequency spectra of the power converter sum currents 50, 50• for the two configurations, as shown in FIG. 4.

A component of the sum current 50 at the fundamental switching frequency f_{SW} of 10 kHz is absent in the ideally symmetric configuration (upper part of FIG. 4), whereas it is clearly visible in the spectrum of the sum current 50• in the case of unequal inductors 32 (lower part of FIG. 4). In a typical power converter, the fundamental switching frequency f_{SW} can in some cases become amplified, leading to an even worse signal quality and a potential instability. To prevent this, according to prior art operation of the power converter, the power converter will need to be operated with reduced control bandwidth and/or reduced system quality, destructing the advantages sought for when applying the interleaving in the first place.

In accordance with the invention, however, the pulse control unit 20 is provided to determine a correction for the pre-determined temporal relationship of the switching of the switching cells 14, 16, 18, given by the phase shift of 120 degrees, from at least one electrical quantity each of each one of the switching cells 14, 16, 18. These electrical quantities could, for instance, be either the inductance values of the inductors 32 of the individual switching cells 14, 16, 18, or the ripple amplitudes of the three switching cell output line currents 34 which could be measured using any available means.

In accordance with the invention, the pulse control unit 20 is further provided to adjust the pre-determined temporal relationship according to the determined correction, such that at least one electrical quantity of a power converter output, as for instance the sum current 50•• in this embodiment, essentially has a zero amplitude at the fundamental switching frequency f_{SW}.

To this end, the pulse control unit 20 comprises a software module 38 (FIG. 1), wherein the method in accordance with the invention is converted into a program code that is implementable in and executable by the pulse control unit 20. The software module 38 resides within the pulse control unit 20. Generally, the software module 38 may as well reside in and may be executable by any other control unit being part of the MRI examination system, and a data communication means may be established between the pulse control unit 20 and the control unit that the software module 38 may reside in.

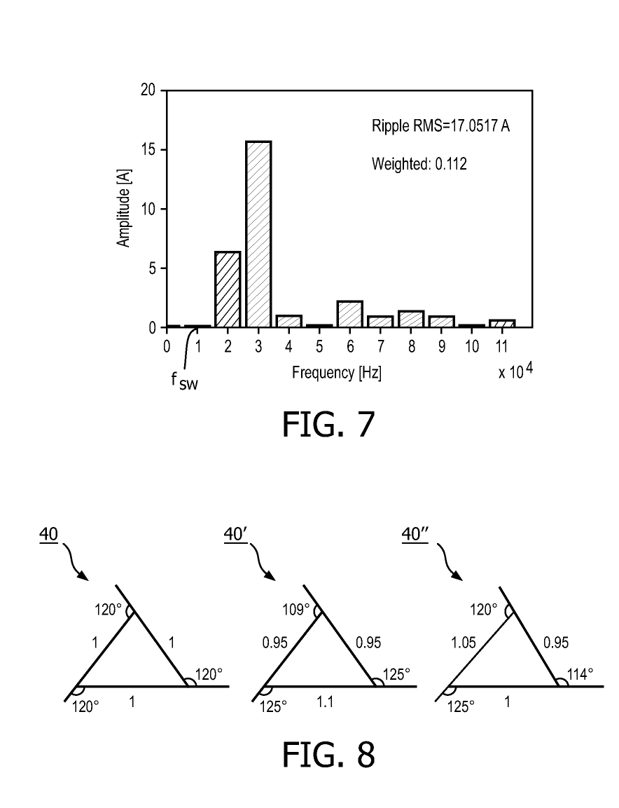

A result of the method applied to the asymmetric configuration given in FIG. 3 is shown in FIG. 6. Again, a spectral diagram in FIG. 7, in particular in comparison to the lower part of FIG. 4, more clearly shows that the component of the sum current 50•• at the fundamental switching frequency f_{SW} has been adjusted to a value of essentially zero. FIG. 7 clearly shows that the component at the fundamental switching frequency f_{SW} has been completely annihilated, in this example at the cost of a modest increase of other harmonics. For those cases in which harmonics are frequency-weighted, as discussed for the gradient coil application above, a net signal quality can be greatly improved. To illustrate this, the harmonic contents with (FIG. 7) and without the correction (FIG. 4) are indicated for two weighting methods: the common RMS (root-mean-square) current ripple level showing a reduction from 17.22 A to 17.05 A, and a frequency-weighted metric, as would be applicable to MRI examination systems, showing a reduction from 0.296 to 0.112; i.e. by almost a factor of three.

To eliminate the electrical quantity at the fundamental switching frequency f_{SW} in the sum current 50•, a vector addition of the amplitudes of the individual switching cell output line currents 34 needs to add up to zero. With the relative amplitudes of individual switching cell output line currents 34 given, this can be accomplished by constructing a closed triangle, with lengths of sides of the triangle equal to the amplitudes of the individual switching cell output line currents 34.

For a certain duty cycle of the pulse width-modulated switching pulses, which is assumed to be equal for all three switching cells 14, 16, 18, a ratio of the amplitude of the cell output line current 34 at the fundamental switching frequency f_{SW} to its peak-to-peak current ripple at the fundamental switching frequency f_{SW} is a fixed number. Due to this fixed ratio, the triangle resulting from the vector addition will have the same shape as another triangle 40 which can be constructed from the amplitudes of the ripples, thus avoiding a Fourier analysis, and is therefore simpler to implement.

Exterior angles of the triangle 40 thus constructed directly indicate the relative phase shifts between the three switching cells 14, 16, 18 (FIG. 8). The left part of FIG. 8 demonstrates the construction of the triangle 40 for the symmetrical configuration: the obtained triangle 40 is equilateral, and all the exterior angles equal 120 degrees, or 2•/3 radian. For a configuration with an amplitude of one output line current 34 being 10% larger than average, and the other two 5% lower, an isosceles triangle 40• with exterior angles of 125.38, 109.25, and 125.38 degrees results (middle part of FIG. 8; angle values shown are rounded to integers). For yet another case with an amplitude of one output line current 34 being 5% smaller than an average and an amplitude of another output line current 34 being 5% higher, a triangle 40•• with exterior angles of 120.25, 114.90, and 124.85 degrees results (right part of FIG. 8). Because a triangle is unambiguously determined by the lengths of all sides, a unique solution always exists that closes the vector sum to a triangle. By doing so, the vector sum of the three switching cell current ripples at the fundamental switching frequency f_{SW} can always be made equal to zero by adjusting the exterior angles; i.e. the phase shifts.

For a number of essentially identical switching cells 14, 16, 18 in excess of three, the method in accordance with the invention still works, but for these cases extra degrees of freedom exist which can be used to eliminate selected additional harmonics.

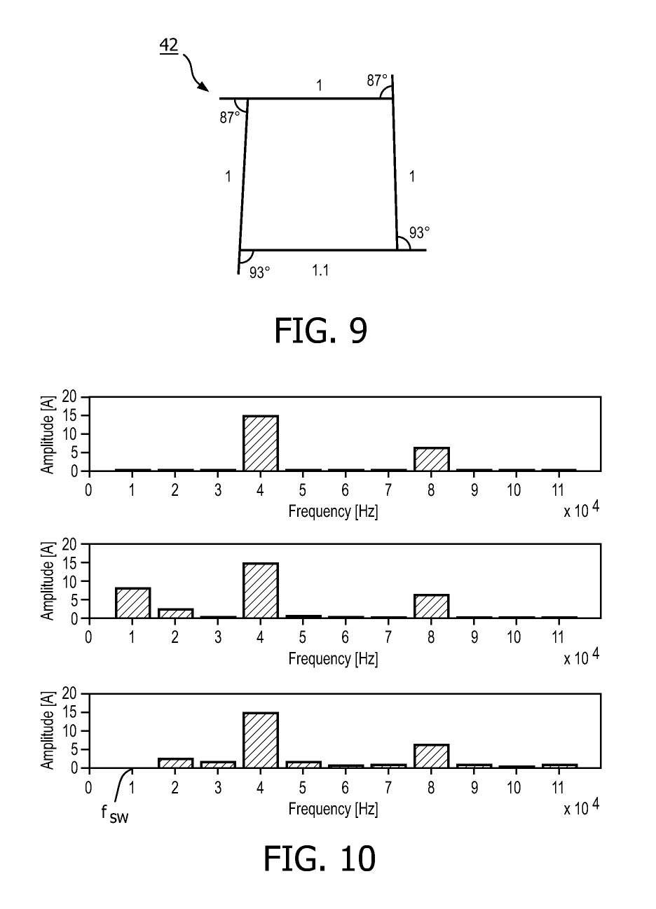

As an example, a configuration with four switching cells 14, 16, 18 is considered. The configuration is identical to the one with three switching cells 14, 16, 18 except for another switching cell 14, 16, 18 being added, so that an illustration of this configuration does not provide additional information and is therefore omitted for simplicity reasons. An amplitude of one switching cell output line current 34 is 10% larger than the other three. A result after application of the method of the invention is shown in FIG. 9. In this special case, an isosceles trapezoid 42 evidently is the most symmetrical construct. Inspection of the construct reveals that exterior angles at a base of the trapezoid 42 are given by arccos (0.05)=87.1 degrees. Although the exterior angles found with the method differ only slightly from that of a symmetric configuration in which all exterior angles equal 90 degrees, the impact on an amplitude of the sum current 50 at the fundamental switching frequency f_{SW} is large, as can be obtained from FIG. 10.

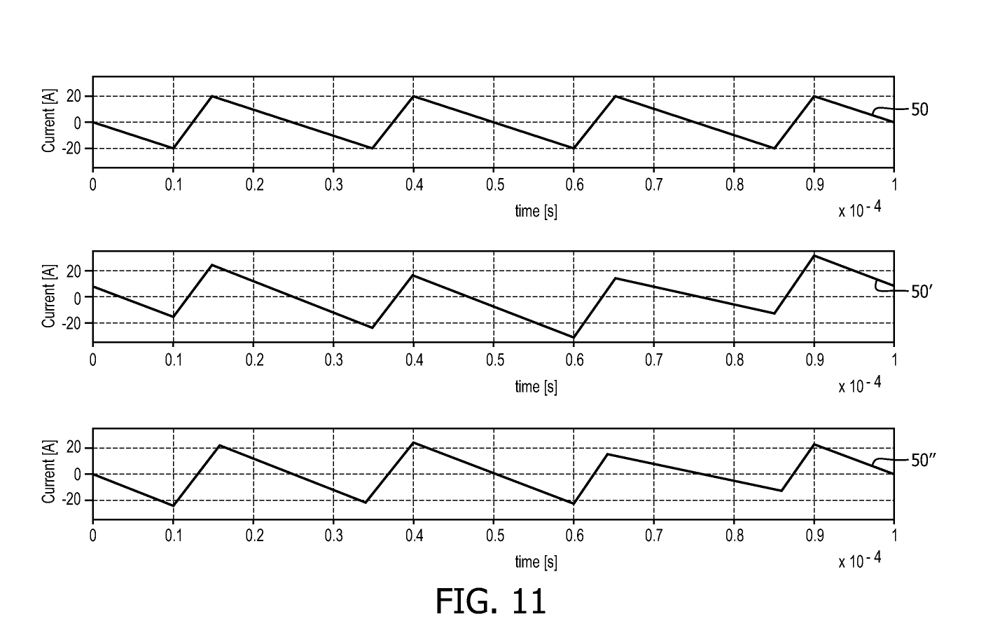

FIG. 10 in an exemplary way shows spectral diagrams for a duty cycle of 0.3 and a fundamental switching frequency f_{SW} of 10 kHz. The top plot applies to the symmetric configuration of switching cells 14, 16, 18 with equal switching cell output line current ripples, when only harmonics numbered with an integer multiple of 4 are present. In the middle plot, one of the output line current ripple amplitudes has been increased by 10%, leading to a presence of a significant fraction of an amplitude at the fundamental switching frequency f_{SW} in the spectrum. In the lower plot, the method to adjust a pre-determined temporal relationship according to a determined correction has been applied. Here, the amplitude at the fundamental switching frequency f_{SW} disappears, at the cost of a slight increase in the third, fifth, and higher harmonics. Finally, in FIG. 11 sum currents 50, 50•, 50•• of the switching cell output line currents 34 are shown in the time domain for the three configurations described above.

While the invention has been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

### REFERENCE SYMBOL LIST

10 interleaved configuration

12 multilevel configuration

14 switching cell

16 switching cell

18 switching cell

20 pulse control unit

22 gradient coil

24 output port

26 output port

28 output line (interleaved)

30 output line (multilevel)

32 Inductor

34 output line current

36 output current

38 software module

40 Triangle

42 Trapezoid

44 switching cell

46 switching cell

48 switching cell

50 sum current

52 switching member

f_{SW} fundamental switching frequency

1. A power converter for powering a gradient coil of a magnetic resonance examination system, comprising:
a plurality of essentially identical switching cells, each switching cell having a plurality of switching members that are provided to switch between a conducting state configuration and an essentially non-conducting state configuration, and the switching cells being provided to switch at at least a fundamental switching frequency fSW and in a pre-determined temporal relationship to each other,
a pulse control unit provided to control the pre-determined temporal relationship of switching of the switching cells by providing switching pulses to the switching members (52) of the switching cells,
wherein the pulse control unit is provided to determine a correction of the phase-shifts between the switching cells for the pre-determined temporal relationship of the switching of the switching cells from at least one electrical quantity each of each one of the plurality of switching cells, and to adjust the pre-determined temporal relationship according to the determined correction, such that at least one electrical quantity of a power converter output essentially has a zero amplitude at the fundamental switching frequency fSW.

2. The power converter as claimed in claim 1, wherein the essentially identical switching cells are connected in parallel and establish common output ports for connecting a load.

3. The power converter as claimed in claim 1, wherein the essentially identical switching cells are connected in series and establish common output ports for connecting a load.

4. The power converter as claimed in claim 1, wherein a number of essentially identical switching cells is three.

5. The power converter as claimed in claim 1, wherein the essentially identical switching cells are designed as H bridges, each comprising semiconductor switches as switching members and at least one inductor.

6. A gradient coil unit of a magnetic resonance examination system, comprising at least one power converter as claimed in claim 1, and at one gradient coil.

7. The gradient coil unit as claimed in claim 6, further comprising a software module that resides in the pulse control unit and is executable by the pulse control unit.

8. A method of operating a power converter, particularly for powering a gradient coil of a magnetic resonance examination system, that comprises a plurality of essentially identical switching cells, each switching cell having a plurality of switching members that are provided to switch between a conducting state configuration and an essentially non-conducting state configuration, and the switching cells being provided to switch at at least a fundamental switching frequency fSW and in a pre-determined temporal relationship to each other, and a pulse control unit provided to control the pre-determined temporal relationship of switching of the switching cells by providing switching pulses to the switching members of the switching cells, the method comprising the following steps:
determine at least one electrical quantity each of each one of the plurality of switching cells
determine a correction of the phase-shifts between the switching cells for the pre-determined temporal relationship of the switching of the switching cells from the electrical quantities of each one of the plurality of switching cells, wherein the electrical quantities are individually assignable to the switching cells,
adjust the temporal relationship of the switching pulses provided to the switching members of the switching cells according to the determined correction such that at least one electrical quantity of a power converter output essentially has a zero amplitude at the fundamental switching frequency fSW.

9. A software module provided to control phase-shifts between switching cells for a pre-determined temporal relationship of switching of switching cells of a power converter, particularly provided for powering a gradient coil of a magnetic resonance examination system, the power converter comprising a pulse control unit provided to control the pre-determined temporal relationship of switching of the switching cells by providing switching pulses to the switching members of the switching cells, and the switching cells are provided to switch at at least a fundamental switching frequency fSW, so as to carry out the following steps:
determine at least one electrical quantity each of each one of the plurality of switching cells,
determine a correction of the phase-shifts between the switching cells for the pre-determined temporal relationship of the switching of the switching cells from the electrical quantities of each one of the plurality of switching cells, wherein the electrical quantities are individually assignable to the switching cells,
adjust the temporal relationship of the switching pulses provided to the switching members of the switching cells according to the determined correction such that at least one electrical quantity of a power converter output essentially has a zero amplitude at the fundamental switching frequency fSW;
wherein the steps are implemented into a program code that is and executable by the pulse control unit of the power converter.
